(19) United States
(12) Patent Application Publication
(10) Pub. No.: US 2015/0108632 A1
(43) Pub. Date: Apr. 23, 2015

(54) THIN FILM WITH NEGATIVE TEMPERATURE COEFFICIENT BEHAVIOR AND METHOD OF MAKING THEREOF

(71) Applicant: Nano and Advanced Materials Institute Limited, Clear Water Bay (HK)

(72) Inventor: Caiming SUN, New Territories (HK)

(73) Assignee: Nano and Advanced Materials Institute Limited

(21) Appl. No.: 14/335,947

(22) Filed: Jul. 21, 2014

Related U.S. Application Data
(60) Provisional application No. 61/961,767, filed on Oct. 23, 2013.

(51) Int. Cl. H01L 23/373; C09D 11/52; C08K 7/10; H01L 21/02

(52) U.S. Cl. CPC H01L 23/3738; H01L 21/02524; C09D 11/52; C08K 7/10; C08K 2201/001
USPC 257/720; 438/122; 252/500

(57) ABSTRACT

A conductive thin film including a binder matrix and semiconductor nanowires dispersed therein is disclosed. The semiconductor nanowires are in the range of 30% to 50% by weight percentage of the thin film. The present invention also discloses a method of making such thin film. The method includes the steps of: mixing a plurality of semiconductor nanowires with a polymer binder to obtain a printing ink; thinning the printing ink with a solvent to achieve a predetermined viscosity; printing the printing ink on a substrate to form a conductive thin film thereon and evaporating the solvent at a rate slower than the evaporation rate of water.

### CROSS REFERENCE TO RELATED APPLICATIONS

This application claims the priority of U.S. Provisional Application No. 61/961,767 filed Oct. 23, 2013, the whole of which is hereby incorporated by reference herein.

### FIELD OF INVENTION

The present invention relates to a thin film, in particular a thin film with negative temperature coefficient behavior.

### BACKGROUND OF INVENTION

Thin films with negative temperature coefficient behavior have shown a wide range of opportunities in industrial and consumer applications, such as compensation of thermal effects in electronic circuits and thermal management in high-power electronic systems. Traditionally, these thin films are made of transition-metal oxide, for instance MnO₂, CoO and NiO with the process of ceramic technology. Such technology required sintering of powders at high temperature (up to 900° C.) which in turn limits the substrate materials that can be used, precluding the use of many lightweight, flexible materials such as paper and polymer film.

Recently, some researchers proposed a printable material based on silicon particles in size range of 10 nm to 100 μm. In order to guarantee the reproducibility, a silicon fraction of over 80% is used in the thin films. Moreover, the electrical transport through this silicon layer is chiefly governed by nanoparticle interconnections. Therefore surface oxidation of these nanoparticles must be prevented, which is a challenge to the synthesis process.

SUMMARY OF INVENTION

In the light of the foregoing background, it is an object of the present invention to provide an alternative composition of a thin film with negative temperature coefficient behavior and the method of making thereof.

In one aspect, the present invention is a conductive thin film including a binder matrix and semiconductor nanowires dispersed therein, wherein the semiconductor nanowires are in the range of 30% to 50% by weight percentage of the thin film.

In one embodiment, the temperature coefficient of resistance of the thin film is in the range of 5%/° C. to 8.1%/° C.

In yet another embodiment, the semiconductor nanowires are dispersed within domains, wherein the domains having diameters of 100 μm to 1000 μm.

According to another aspect of the present invention, a method of producing a conductive thin film is disclosed. The method includes the steps of mixing a plurality of semiconductor nanowires with a polymer binder to obtain a printing ink; and printing the printing ink on a substrate to form the conductive thin film thereon.

The semiconductor nanowires are in the range of 30% to 50% by weight percentage of the thin film.

In one embodiment, the method further includes the steps of thinning the printing ink with a solvent to achieve a predetermined viscosity and evaporating the solvent at an evaporation slower than the evaporation rate of water.

In one embodiment, the solvent is selected from a group consisting of polyethylene glycol and ethylene glycol.

In another aspect, the present invention is a conducting ink formed by a process including the steps of mixing a plurality of semiconductor nanowires with a polymer binder to obtain a mixture and thinning the mixture with a solvent to achieve a predetermined viscosity of the ink. The semiconductor nanowires are in the range of 30% to 50% by weight percentage of the ink and the solvent has an evaporation rate slower than 10⁻⁴ kg/m²-s at room temperature and ambient environment.

The present invention can be conducted at room temperature without involving high temperature, high pressure, or costly equipment and hazardous materials. Furthermore, nanowires bear higher crystal quality than nanoparticles. Sparsely interconnected nanowire networks form continuous films with good conductivity for electronic devices which can be promisingly applied for semiconductor layer in thin film transistors (TFTs) with great mobility.

### BRIEF DESCRIPTION OF THE DRAWINGS

For a more complete understanding of the present invention, reference is made to the following detailed description and accompanying drawings, in which:

FIG. 1 shows a flow diagram for a process for making a silicon nanowire-based thin film according to one embodiment of the present invention;

FIG. 2 shows the scanning electron microscope (SEM) images of silicon nanowires on an etched silicon wafer according to one embodiment of the present invention. FIG. 2A and FIG. 2B show the cross-sectional view and the plain view of the silicon nanowires respectively;

FIG. 3 shows the Transmission electron microscopy (TEM) images of a silicon nanowire according to the embodiment as shown in FIG. 2. FIG. 3A is a low resolution TEM image showing the whole silicon nanowire and FIG. 3B is a high resolution TEM image showing the surface of the silicon nanowire;

FIG. 4 shows a printed silicon nanowire film using 2-Propanol as the solvent according to one embodiment of the present invention. FIG. 4A and FIG. 4B show an optical photograph and a SEM image of the silicon nanowire film using 2-Propanol as the solvent respectively. FIG. 4C is an enlarged image of FIG. 4B;

FIG. 5 shows a printed silicon nanowire film using water as the solvent according to one embodiment of the present invention. FIG. 5A and FIG. 5B show an optical photograph and a SEM image of the silicon nanowire film using water as the solvent respectively. FIG. 5C is an enlarged image of FIG. 5B;

FIG. 6 shows a silicon nanowire film formed using drop-casting technique according to one embodiment of the present invention;

FIG. 7 shows a silicon nanowire film formed using screen-printing technique according to one embodiment of the present invention; and

FIG. 8 shows the behaviour of a silicon nanowire film according to one embodiment of the present invention. FIG. 8A shows a temperature sensor fabricated using the silicon nanowire film according to one embodiment of the present invention and FIG. 8B shows the resistance to temperature curve (R-T curve) of the temperature sensor as shown in FIG. 8A.

### DETAILED DESCRIPTION OF THE PREFERRED EMBODIMENTS

As used herein and in the claims, “comprising” means including the following elements but not excluding others.

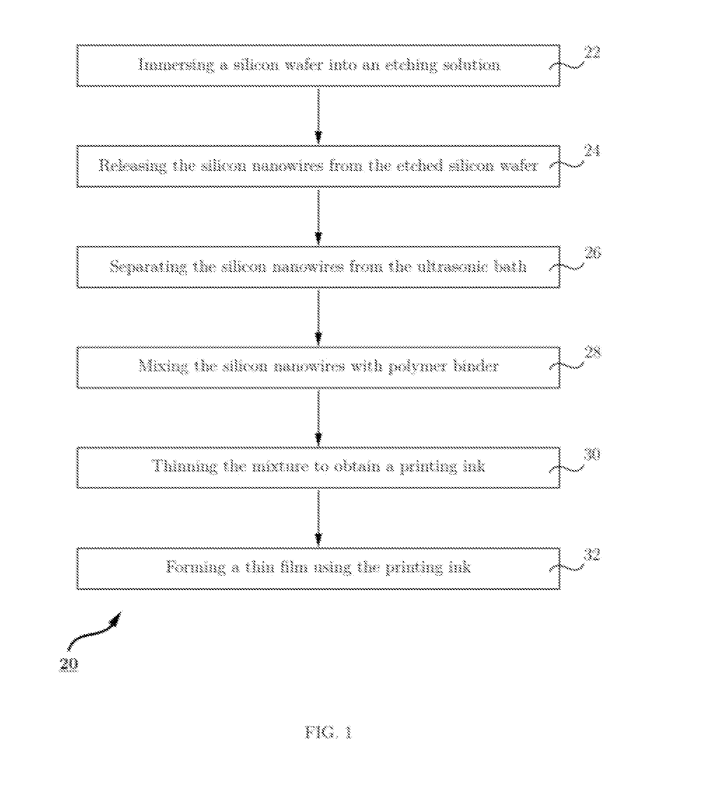

FIG. 1 shows a method 20 of producing silicon nanowire-based thin film. The method 20 begins with a step 22, in which a silicon wafer is immersed into a hydrofluoric acid-silver nitrate (HF—AgNO₃) solution, serving as the etching solution, to produce silicon nanowires. In this synthesis, which is known as metal-assisted chemical etching (MaCE), solution-nucleated metal plays the role of a nanoscale electrode in the electrochemical etching of a single-crystalline silicon wafer. The metal nanoparticles, such as silver, oxidize silicon that is in contact with them by taking electrons from silicon. The oxidized silicon, or silicon oxide (SiO₂), is then etched away by hydrofluoric acid (HF) in the etching solution, leaving a pit or hole on the silicon surface. As the electrochemical redox reaction proceeds, the metal nanoparticles sink down further and remove underlying silicon. Finally, silicon nanowires result from areas where no metal is present.

The second step 24 of the method 20 is to immerse the etched silicon wafer in a potassium hydroxide (KOH) solution in order to release the silicon nanowires from the etched silicon wafer. Afterwards, the silicon nanowires are dispersed into a solution by an ultrasonic bath and further separated from the dispersions using centrifuge in step 26. The silicon nanowires are then mixed with a polymer binder at step 28 at nanowire-to-binder weight ratios of 1:2 to 1:1. In order to facilitate the afterwards fabrication processing, the viscosity of the mixture of silicon nanowires and the polymer binder are adjusted by adding a solvent therein, thereby obtaining a printing ink, in step 30. The last step 32 of the method 20 is to form a thin film using the printing ink obtained in step 30.

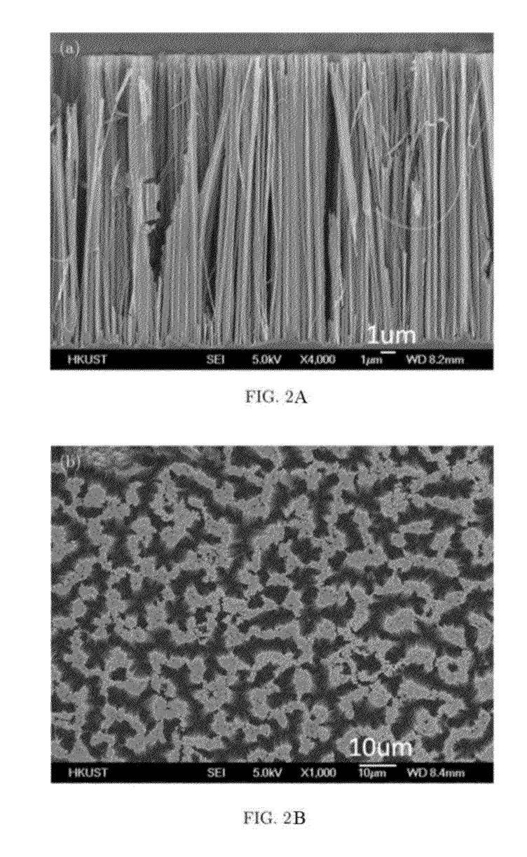

In order to better illustrate the present invention, an example is provided herein. Boron-doped p-type silicon (100) wafer with a resistivity of 15-25 Ω-cm was used as a starting wafer for synthesis of silicon nanowires. Etching was performed in an etching solution consisting of 4.8M of HF, 0.03M of AgNO₃ and deionized (DI) water for 2 hours at room temperature. The scanning electron microscopy (SEM) images of as-etched silicon nanowires on the wafer are shown in FIG. 2, of which FIG. 2A is the cross-sectional and FIG. 2B is the plan-view image. It should be observed that a dense, vertical array of silicon nanowires of length about 20 μm was obtained.

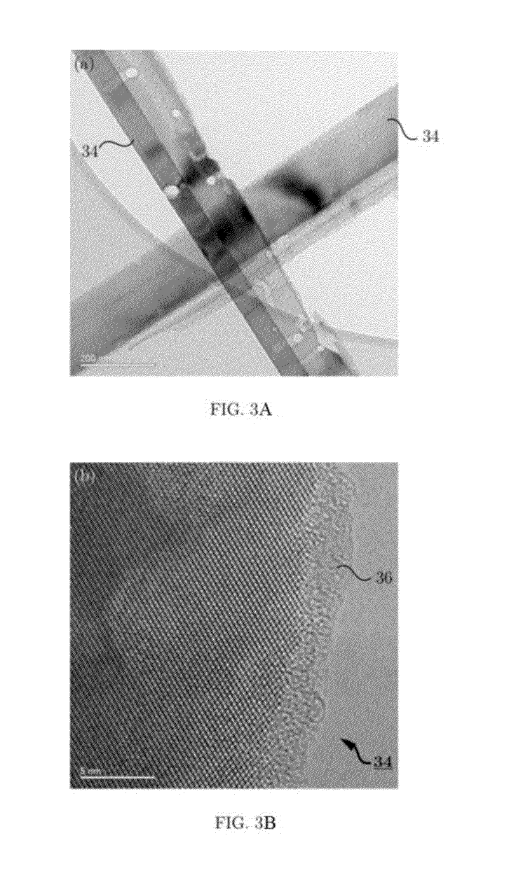

The silicon nanowires were then released into ethanol from as-etched silicon wafers by sonication in an ultrasonic bath. Afterwards, the silicon nanowires in the ethanol were centrifuged three times using rotational speed of 10,000 rpm. The duration of each cycle is 10 minutes. Finally, the silicon nanowires were dried in vacuum oven at 40° C. The morphology of individual silicon nanowire was examined by transmission electron microscopy (TEM). The corresponding images are shown in FIG. 3. Referring to FIG. 3A, the diameters of silicon nanowires 34 were in the range of 50 nm to 150 nm. Referring now to FIG. 3B, which is a high-resolution TEM image of the surface of a particular silicon nanowire 34, a native silicon oxide 36 layer below 2 nm was found on the surface of the silicon nanowire 34. This indicates that the surface oxidation of silicon nanowires 34 can be ignored for electrical interconnection between silicon nanowires 34 in the MaCE process. From weight measurements on the wafer before and after the release of the silicon nanowires, it was found that about 50% of silicon in the wafer was fabricated to silicon nanowires. Therefore, for standard 4-inch silicon starting wafers as used in the present example, more than one gram of silicon nanowires can be obtained by the aforesaid process.

After obtaining the silicon nanowires, a printing ink is obtained by mixing the silicon nanowires with a polymer binder and a solvent. In order to achieve a desirable resistance of the resulting thin film, which is in the order of MΩ, a solvent with evaporation rate solwer than that of water is used. In order to illustrate the effect of the evaporation rate of the solvent to the resulting thin film, three inks with different composition were prepared.

### Example 1

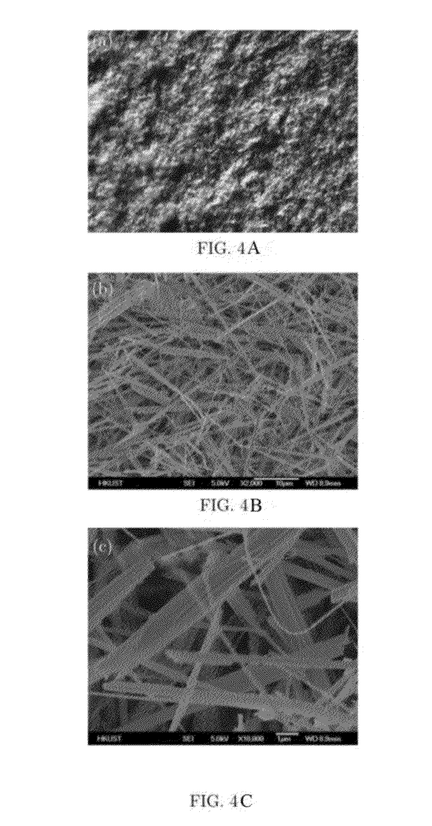

In this example, 2-propanol was used as the solvent. 0.1 g of silicon nanowires obtained using the aforesaid method were mixed with 0.1 mg of commercial polymer binder (LUMITEX â [symbol] [symbol] GBX, Karan Texchem Pvt. Ltd.), which was dissolved in 2 ml of 2-propanol. Afterwards, a thin film, which is shown in FIG. 4A, was obtained by screen printing this ink over a substrate. Referring to FIG. 4B and FIG. 4C, scanning electron microscope (SEM) images of the thin film as shown in FIG. 4A and an enlarged image of the central portion of the thin film are shown respectively. It should be observed that the silicon nanowires are randomly distributed in the thin film which results into a very high resistivity, i.e. over giga Ω-cm. It is because propanol is very easy to vaporize and make the printed film dry quite fast. There is no enough time for silicon nanowire to assemble during this fast solvent evaporation. Such a high resistivity makes the printed film not suitable for any NTC applications.

### Example 2

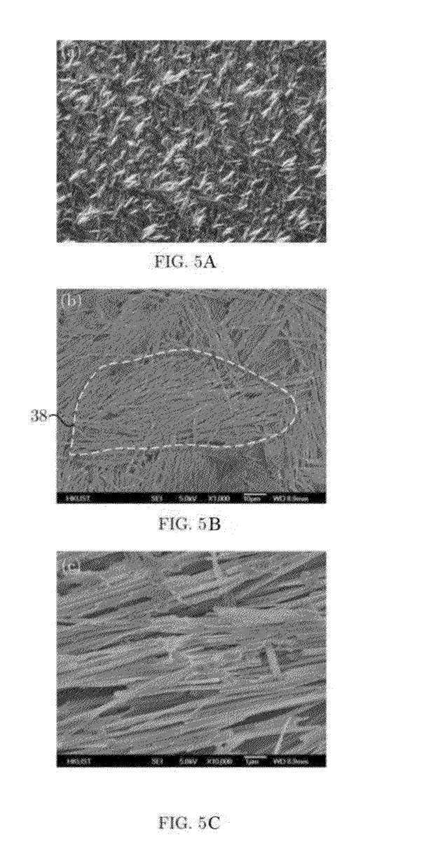

Deionized water was used as the solvent of the printing ink in the second example. 0.1 g of silicon nanowires and 0.1 mg of commercial polymer binder (LUMITEX â [symbol] [symbol] GBX, Karan Texchem Pvt. Ltd.) dissolved in 2 ml of deionized water was used. The thin film obtained thereof is shown in FIG. 5A. FIG. 5B is the SEM image of the thin film as shown in FIG. 5A. Well-aligned nanowires within domain 38 are observed therein. The domain 38, as shown in FIG. 5B and FIG. 5C, has a diameter of 100 μm. It should be noted that silicon nanowires are also found within the thin film in areas where a domain cannot be defined. The resistivity of this thin film, which is around 10 Mega Ω-cm, is much lower than that obtained in the first example. It is because that the well-aligned silicon nanowires contribute to electrical path which makes this printed film a desirable NTC material.

### Example 3

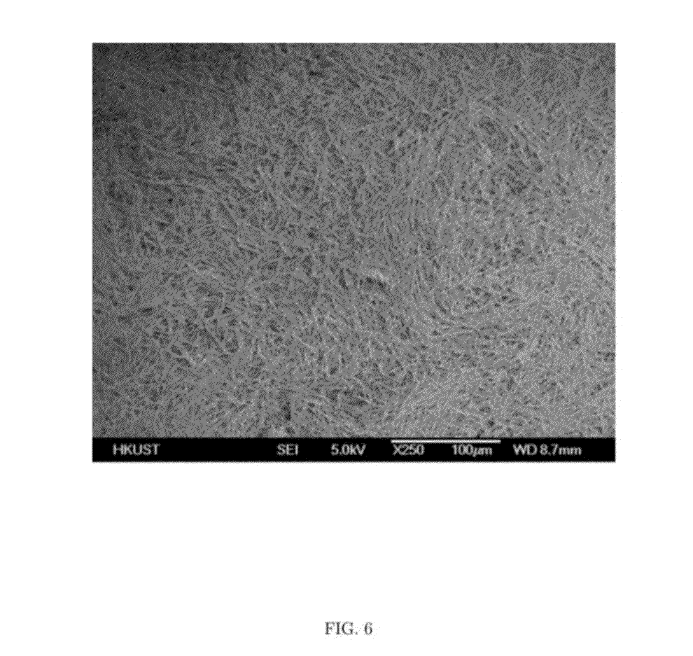

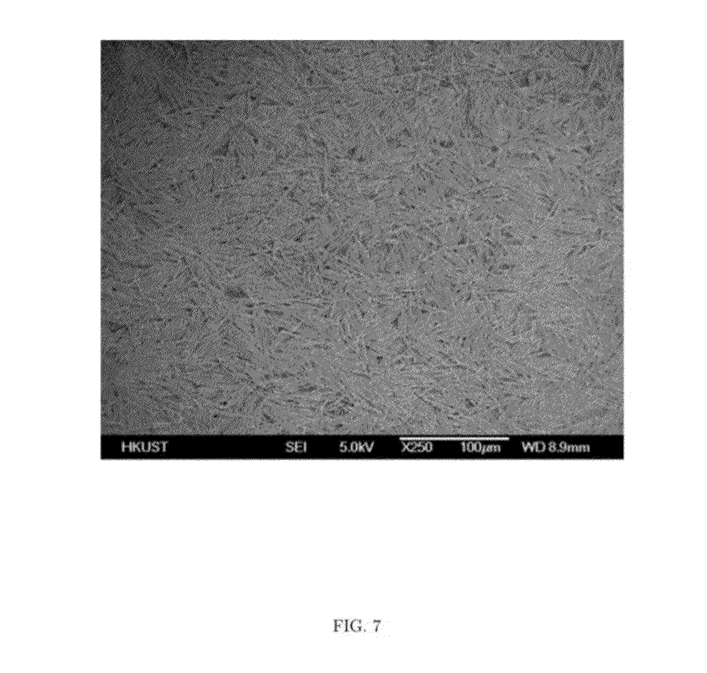

In the third example, 100 mg of commercial polymer binder (LUMITEX â [symbol] [symbol] GBX, Karan Texchem Pvt. Ltd.) was dissolved into 0.7 ml of ethylene glycol, serving as a solvent. After addition of 0.1 g silicon nanowires, the mixtures were homogenized in a rotary mixer for two minutes. Eventually, two silicon nanowire-based thin films were formed by drop casting the printing ink onto predefined patterns. In this example, the pattern used is a 1 cm×1 cm square. The thin films were examined using scanning electron microscope after drying overnight. The SEM image of the thin film obtained using drop casting and screen printing are shown in FIG. 6 and FIG. 7 respectively. Both drop-casted and screen-printed films show continuous films. The drop-casted film has a thickness over 100 μm with high surface roughness as shown in FIG. 6, whereas for the screen-printed layer, the thickness is 10 μm and the surface is smoother compared to the drop-casted film.

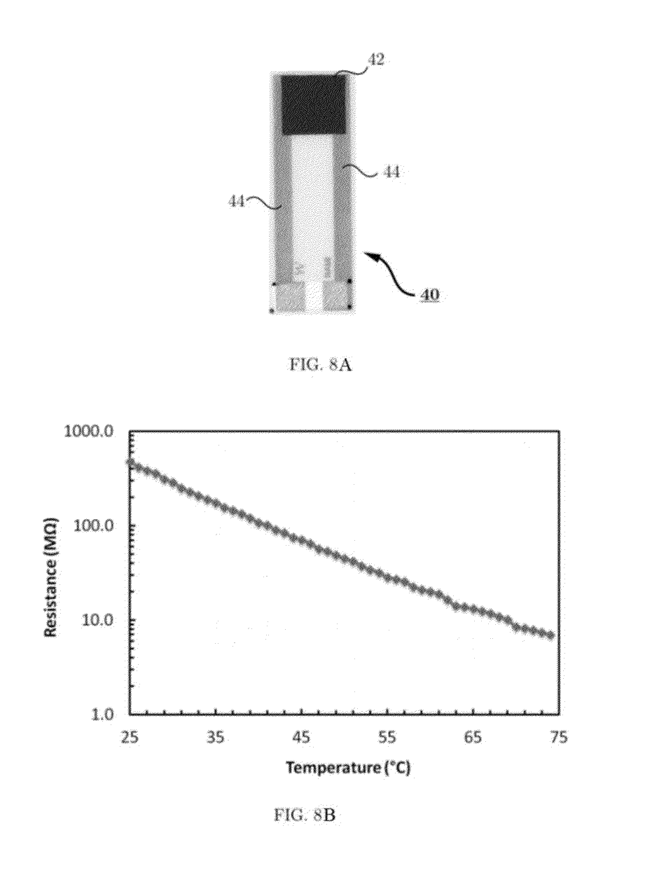

One 1 cm×1 cm temperature sensor was then fabricated using the screen-printed thin film as shown in FIG. 7. FIG. 8A shows the temperature sensor 40 obtained therefrom. The temperature sensor 40 includes a 1 cm×1 cm thin film 42 and two electrodes 44. The electrodes 44 are coupled to the thin film 42 at two opposing ends. The resistance change of the temperature sensor 40 with respect to temperature change was then measured. The corresponding resistance to temperature curve (R-T curve) of the temperature sensor 40 is shown in FIG. 8B. The temperature sensor 40 shows a negative temperature coefficient behavior as governed by equation (1).

$$R = {R}_{25} exp ( \frac{B}{T} - A ) \qquad ( 1 )$$

where R is the resistivity as a function of temperature T, B is the material constant and correlates with temperature sensitivity, and R₂₅ is the resistance at 25° C. as reference.

From the R-T curve as shown in FIG. 8B, the temperature coefficient of resistance α, which is governed by equation (2), of the thin film 42 of the temperature sensor 40 is 8.1%/° C. in average from 25° C. to 75° C., which approaches the reported value of 8.0-9.5%/° C. for intrinsic silicon bulk material near room temperature.

$$α = \frac{1}{R} \frac{d R}{d T} \qquad ( 2 )$$

where α is the temperature coefficient of resistance and R is the resistivity as shown in equation (1).

The exemplary embodiments of the present invention are thus fully described. Although the description referred to particular embodiments, it will be clear to one skilled in the art that the present invention may be practiced with variation of these specific details. Hence, this invention should not be construed as limited to the embodiments set forth herein.

For example, silicon nanowires are used in the aforementioned embodiments and example. However, other semiconductor nanowire, for instance germanium and metal oxide semiconductor nanowires, may be used according to the user's preference. Furthermore, deionized water and ethylene glycol are used as the solvent in the printing ink. Other solvent with evaporation rate slower than that of water, for instance polyethylene glycol, could also be used.

Sonication with the help of potassium hydroxide is adopted to release the silicon nanowires from an etched silicon wafer in the aforesaid examples. Nonetheless, mechanical scraping by razor blade and wet chemical etching by alkali hydroxides can also be adopted to release the nanowires from the etched wafer.

What is claimed:

1. A conductive thin film comprising a binder matrix and semiconductor nanowires dispersed therein, wherein said semiconductor nanowires are in the range of 30% to 50% by weight percentage of said thin film.

2. The conductive thin film of claim 1, wherein the temperature coefficient of resistance of said thin film is in the range of 5%/° C. to 8.1%/° C.

3. The conductive thin film of claim 1, wherein said semiconductor nanowires are dispersed within domains, wherein said domains having diameters of 100 μm to 1000 μm.

4. The conductive thin film of claim 1, wherein said semiconductor nanowires are laterally dispersed in said thin film.

5. The conductive thin film of claim 1, wherein said semiconductor nanowires are made of a material selected from a group consisting of silicon, germanium and metal oxide.

6. A method of producing a conductive thin film comprising the steps of:
a) mixing a plurality of semiconductor nanowires with a polymer binder to obtain a printing ink; and
b) printing said printing ink on a substrate to form said conductive thin film thereon;
wherein said semiconductor nanowires are in the range of 30% to 50% by weight percentage of said thin film.

7. The method of claim 6 further comprising the steps of:
a) thinning said printing ink with a solvent to achieve a predetermined viscosity; and
b) evaporating said solvent at a rate slower than the evaporation rate of water.

8. The method of claim 7, wherein said evaporation rate of water is 10⁻⁴ kg/m²-s at room temperature and ambient environment.

9. The method of claim 7, wherein said solvent is selected from a group consisting of polyethylene glycol and ethylene glycol.

10. The method of claim 7, wherein said predetermined viscosity in the range of 100 cps to 10,000 cps.

11. The method of claim 6, wherein said step of printing said printing ink is conducted using a technique selected from a group consisting of screen printing technique and drop casting technique.

12. The method of claim 6 further comprising a step of producing said semiconductor nanowires by metal-assisted chemical etching, wherein said step of producing said semiconductor nanowires further comprises the steps of:
a) providing a semiconductor wafer;
b) etching said semiconductor wafer in an etching solution to form an etched wafer; and
c) immersing said etched wafer in a potassium hydroxide solution to release said semiconductor nanowires from said etched wafers;
wherein said metal-assisted chemical etching is conducted under room temperature for two hours.

13. The method of claim 12, wherein said etching solution comprises:
a) 4.8M of hydrofluoric acid;
b) 0.03M of silver nitrate; and
c) deionized water.

14. The method of claim 12 further comprising the steps of:
a) dispersing said silicon nanowires into a solution by an ultrasonic bath;
b) centrifuging said solution to separate said semiconductor nanowires dispersed therein; and
c) drying said semiconductor nanowires on vacuum oven;
wherein said step of centrifuging is performed three times at 10,000 rpm and each cycle is 10 minutes; wherein said step of drying is conducted at 40° C.

15. A conducting ink formed by a process comprising the steps of:
a) mixing a plurality of semiconductor nanowires with a polymer binder to obtain a mixture; and
b) thinning said mixture with a solvent to achieve a predetermined viscosity of said ink;
wherein said semiconductor nanowires are in the range of 30% to 50% by weight percentage of said ink and said solvent has an evaporation rate slower than the evaporation rate of water.

16. The conducting ink of claim 15, wherein said evaporation rate of water is 10⁻⁴ kg/m²-s at room temperature and ambient environment.

17. The conducting ink of claim 15, wherein said solvent is selected from a group consisting of polyethylene glycol and ethylene glycol.

18. The conducting ink of claim 15, wherein said predetermined viscosity in the range of 100 cps to 10,000 cps.

19. The conducting ink of claim 15, wherein said semiconductor nanowires are made of a material selected from a group consisting of silicon, germanium and metal oxide.
